(19) United States
(12) Patent Application Publication
(10) Pub. No.: US 2025/0194321 A1
(43) Pub. Date: Jun. 12, 2025

(54) Ultra Thin Light Emitting Diodes Electrode Assembly, Method for Manufacturing Thereof and Lighting Source Comprising the Same

(71) Applicant: Kookmin University Industry Academy Cooperation Foundation, Seoul (KR)

(72) Inventor: Young Rag DO, Seoul (KR)

(21) Appl. No.: 18/977,347

(22) Filed: Dec. 11, 2024

(30) Foreign Application Priority Data
Dec. 11, 2023 (KR) 10-2023-0178751

(51) Int. Cl. H10H 29/03; H10H 29/14

(52) U.S. Cl. CPC H10H 29/03; H10H 29/142

(57) ABSTRACT

The present disclosure relates to an LED electrode assembly, and more specifically to an ultra-thin LED electrode assembly, a manufacturing method thereof and a light source including the same. According to the present disclosure, even an LED element having a small aspect ratio that is difficult to receive a positive dielectrophoretic force can be easily self-aligned on a target electrode, and the LED element can be self-aligned on an electrode regardless of the distance between two electrodes forming an electric field and the size of the LED element.

### CROSS-REFERENCE TO RELATED APPLICATION(S)

This application claims priority to and the benefit of Korean Patent Application No. 10-2023-0178751, filed on Dec. 11, 2023, the disclosure of which is incorporated herein by reference in its entirety.

### TECHNICAL FIELD

The present disclosure relates to an LED electrode assembly, and more specifically to an ultra-thin LED electrode assembly, a manufacturing method thereof and a light source including the same.

### RELATED ART

LEDs can implement excellent color and high efficiency, and are environmentally friendly materials, and thus, they are used as key materials for various light sources and displays. Additionally, in line with this market situation, research and development on LED materials that can achieve high efficiency, low cost and high stability are also actively being conducted recently.

In line with this research in the material field, many attempts have been made recently to implement a small size of LED elements used in light sources from mini-LEDs to micro-LEDs and even nano-LEDs in order to implement a high-resolution and high-brightness light source. However, these attempts have a technical difficulty in how to mount LED elements that are becoming smaller and smaller than what can be distinguished with the naked eye on even smaller electrodes without defects.

Recently, attempts have been made to overcome this difficulty through self-alignment, which allows LED elements to move and mount on electrodes by themselves through a dielectrophoretic force received by the LED elements under an electric field. For example, Korean Registered Patent Publication No. 10-2414266 discloses a display implemented by using a dielectric force through an electric field formed between two electrodes to self-align an LED element across two electrodes.

However, the self-alignment of LED elements using a dielectric force requires that the LED element receive a positive dielectric force that moves between the two electrodes forming an electric field in order to be mounted so as to contact the two electrodes due to the movement and alignment mechanism of the element. However, if the length of the LED element is smaller than an interval between the two electrodes, it can only be aligned so as to contact only any one of the two electrodes. Therefore, in any case, the LED element cannot be aligned so as to electrically contact the two adjacent electrodes by using a positive dielectric force. In addition, the positive dielectrophoretic force, which is the main force that self-aligns the LED element, is advantageous in the shape of the LED element in a rod shape with a large aspect ratio, and there are limitations in that the shape of the LED element, the length of the LED element and the interval between the two electrodes must be controlled to enable self-alignment, such as implementing the interval between the two electrodes to be less than or equal to the length of the LED element.

### SUMMARY

The present disclosure has been devised to solve the above-described problems, and an object of the present disclosure is to provide an ultra-thin LED electrode assembly that is capable of self-aligning even an LED element having a small aspect ratio that is difficult to receive a positive dielectrophoretic force by overcoming the limitations of self-alignment by a positive dielectrophoretic force, and is capable of self-aligning an LED element on an electrode regardless of the distance between two electrodes forming an electric field and the size of the LED element, a method for manufacturing the same and a light source including the same.

In addition, another object of the present disclosure is to provide an ultra-thin LED electrode assembly that is capable of mounting an LED element such that the light-emitting surface of the LED element being driven becomes a front surface facing a user or a target while increasing the ratio of ultra-thin LED elements that are self-aligned on an electrode and are drivable by an AC power source to minimize side contact that may cause an electrical short circuit, a method for manufacturing the same and a light source including the same.

In order to solve the above-described problems, the present disclosure provides a method for manufacturing an ultra-thin LED electrode assembly, the method including injecting a solution having a plurality of ultra-thin LED elements on a first electrode line, wherein at least two first electrodes whose side surfaces are spaced apart are spaced apart from each other; applying power having a frequency of 500 Hz or less to the first electrode line to form an electric field; moving ultra-thin LED elements located within the electric field into upper surfaces of the first electrodes; and forming a second electrode line on the ultra-thin LED elements arranged within the upper surfaces of the first electrodes.

According to an embodiment of the present disclosure, the power may have a frequency of 1 to 500 Hz and a voltage of 5 to 100 Vpp.

In addition, the viscosity of a solvent in the solution may be 50 cP or less.

In addition, the dielectric constant (E) of a solvent in the solution may be 5 to 50.

In addition, the ultra-thin LED element may be formed by stacking layers including a first conductive semiconductor layer, a photoactive layer and a second conductive semiconductor layer, and may further include a rotation-inducing film surrounding a side surface of the ultra-thin LED element in order to generate a rotational torque based on an axial direction perpendicular to a direction in which the layers are stacked.

In addition, the rotation-inducing film may have a dielectric constant (ε) of 3 to 26.

In addition, the ultra-thin LED element may have a ratio (b/a) of a thickness (b), which is a length in the stacking direction, to a longitudinal length (a) in a cross-section perpendicular to the stacking direction of the layers, of more than 0 and 2.0 or less.

In addition, the ratio (b/a) for the ultra-thin LED element may be more than 0 and 1.8 or less.

In addition, the present disclosure provides an ultra-thin LED electrode assembly, including a first electrode line including at least two first electrodes that are spaced apart from each other such that side surfaces thereof are opposite to each other; a plurality of ultra-thin LED elements including a first ultra-thin LED element that is positioned within an upper surface of the first electrode; and a second electrode line arranged on the first ultra-thin LED element, wherein a first electrode upper surface settling ratio calculated according to Mathematical Formula 1 below satisfies 40% or more:

$$[ Mathematical Formula 1 ]$$

$$First electrode upper surface settling ratio ( \% ) = \frac{Number of first ultra - thin LED elements}{Total number of ultra - thin LED elements} \times 100$$

Herein, the number of ultra-thin LED elements refers to a total number of ultra-thin LED elements placed within a unit area (1 mm²) of the first electrode line and a number of first ultra-thin LED elements.

According to an embodiment of the present disclosure, the ultra-thin LED element may be formed by stacking a plurality of layers including a first conductive semiconductor layer, a photoactive layer and a second conductive semiconductor layer, and may include a first surface and a second surface facing each other in a thickness direction, and wherein a drivable mounting ratio, which is a ratio of the total number of a number of third ultra-thin LED elements mounted such that the first surface contacts an upper surface of the first electrode and the second surface contacts a second electrode line and a number of fourth ultra-thin LED elements mounted such that the second surface contacts an upper surface of the first electrode and the first surface contacts a second electrode line among the number of first ultra-thin LED elements arranged within a unit area (1 mm²) of the first electrode line, is 40% or more, more preferably, 45% or more, 50% or more, 55% or more, 60% or more, or 70% or more.

In addition, an interval between adjacent first electrodes may be 2 to 10 μm.

In addition, the ultra-thin LED element may have a thickness of 0.5 to 1.5 μm, which is a length in a direction in which the layers are stacked, and a longitudinal length in a cross-section perpendicular to a direction in which the layers are stacked of 0.5 to 3.0 μm.

In addition, the first electrode upper surface settling ratio calculated according to Mathematical Formula 1 may be 80% or more, and the drivable mounting ratio may be 50% or more.

In addition, the present disclosure provides a light source, including the ultra-thin LED electrode assembly according to the present disclosure.

According to an embodiment of the present disclosure, it may further include a color conversion material excited by light irradiated from the ultra-thin LED electrode assembly.

In addition, the ultra-thin LED element equipped in the ultra-thin LED electrode assembly may be an element that emits any one type of light color among UV, blue, green, yellow, amber and red.

Hereinafter, the terms used in the present disclosure are defined.

In the description of the embodiments according to the present disclosure, when it is described as being formed “above”, “upper”, on “top”, “below”, “lower” or on “bottom” of each layer(s) or region(s), “above”, “upper”, on “top”, “below”, “lower”, or on “bottom” include both meanings of “directly” and “indirectly.”

In addition, as a term used in the present disclosure, the “drivable mounting ratio” means a ratio of the number of LED elements mounted in a drivable form among all LED elements mounted on an upper surface of the first electrode. In this case, the LED element mounted in a drivable form means an LED element mounted such that the first surface among the first surface and the second surface, which are opposite to each other in a thickness direction in which a plurality of layers forming the LED element are stacked, are in contact with the upper surface of the first electrode, and an LED element mounted such that the second surface of the LED element is in contact with the upper surface of the first electrode. Ultimately, the drivable mounting ratio is a ratio of the total number (L) of first ultra-thin LED elements arranged on the upper surface of the first electrode within the unit area (1 mm²) of the first electrode line to the total number (M) of ultra-thin LED elements mounted such that the first surface of the first ultra-thin LED elements is in contact with the upper surface of the first electrode and the total number (N) of ultra-thin LED elements mounted such that the second surface is in contact with the upper surface of the first electrode, and it is calculated using the mathematical equation [(M+N)/L]×100.

Meanwhile, it is disclosed that the present disclosure was invented with the support of the following national research and development projects.
[National Research and Development Project 1 that supported this invention]
[Project Identification Number] 1711130702
[Project Number] 2021R1A2C2009521
[Name of Ministry] Ministry of Science and ICT
[Name of Project Management (Specialized) Institution] National Research Foundation of Korea
[Title of Research Project] Mid-career researcher support project
[Title of Research Task] Dot-LED material and display source/application technology development
[Contribution Ratio] 50/100
[Name of Task Performance Institution] Kookmin University Industry-Academic Cooperation Foundation
[Research Period] Mar. 1, 2021 to Feb. 28, 2026
[National Research and Development Project 2 that supported this invention]
[Project Identification Number] 1711199993
[Project Number] 00281346 (RS-2023-00281346)
[Name of Ministry] Ministry of Science and ICT
[Name of Project Management (Specialized) Institution] National Research Foundation of Korea
[Title of Research Project] Nano and material technology development project (strategic)
[Title of Research Task] Development of high-resolution 300 ppi inorganic light-emitting display material and process technology with an intrinsic elasticity of 30% or more
[Contribution Ratio] 50/100
[Name of Task Performance Institution] Hongik University Industry-Academic Cooperation Foundation
[Research Period] Aug. 1, 2023 to Dec. 31, 2027

The method for manufacturing an ultra-thin LED electrode assembly according to the present disclosure can accommodate an LED element at a high ratio within a single electrode surface without being restricted by the distance between two electrodes forming an electric field or the size of the LED element, even when using an LED element having a small aspect ratio that makes it difficult to receive a positive dielectrophoretic force or not having a separate layer such as a magnetic layer for attracting the electrode. In addition, by increasing the ratio of ultra-thin LED elements mounted so as to be operable by an AC power source among the ultra-thin LED elements accommodated within the electrode surface, side contact that can cause an electrical short can be minimized, and accordingly, it can be widely applied as various light sources.

### BRIEF DESCRIPTION OF THE DRAWINGS

FIGS. 1 and 2 are drawings of an ultra-thin LED electrode assembly according to one embodiment of the present disclosure, wherein FIG. 1 is a plan view of an ultra-thin LED electrode assembly, and FIG. 2 is a cross-sectional mimetic diagram along the X-X′ boundary line of FIG. 1.

FIG. 3 is a cross-sectional diagram of an ultra-thin LED element included in one embodiment of the present disclosure.

FIG. 4 is a mimetic diagram for explaining the self-alignment of an ultra-thin LED element by a dielectrophoretic force, wherein (a) is a drawing in which a solution including an ultra-thin LED element is processed on first electrodes that are spaced apart from each other, (b) is a drawing showing a state in which an ultra-thin LED element is self-aligned according to a negative dielectrophoretic force by a power applied to the first electrode, and (c) is a drawing showing a state in which an ultra-thin LED element is self-aligned according to a positive dielectrophoretic force by a power applied to the first electrode.

FIGS. 5 to 7 are graphs simulating the distance moved by an ultra-thin LED element under different conditions in a state where a solution including a cylindrical ultra-thin LED element having a thickness of 1.05 μm in a direction in which layers are stacked on a first electrode having a width of 10 μm and spaced apart from each other by 2 μm, a surface diameter of 750 nm perpendicular to the direction of stacking, and including an n-type conductive semiconductor layer, a photoactive layer and a p-type conductive semiconductor layer is processed, wherein FIG. 5 is a graph simulating the distance moved by the ultra-thin LED element by the action of four forces when the voltage of the power applied to the first electrode is fixed at 10 Vpp and the frequency is changed, FIG. 6 is a graph simulating the distance moved by the ultra-thin LED element by changing the type of solvent, and FIG. 7 is a graph simulating the distance moved by the ultra-thin LED element by changing the voltage of the applied power.

FIG. 8 is a cross-sectional view of an ultra-thin LED element according to one embodiment of the present disclosure.

FIG. 9 is a mimetic diagram showing an ultra-thin LED element placed in a solvent above a first electrode where an electric field is formed in step S3 according to one embodiment of the present disclosure, moving into the upper surface of the first electrode by electro-osmotic pressure and then being self-aligned, wherein (a) is a mimetic diagram showing a rotational torque generated in the element based on the x-axis perpendicular to the thickness direction (d) of the ultra-thin LED element, and (b) is a mimetic diagram showing that one end surface of the ultra-thin LED element in the thickness direction is mounted such that it contacts the upper surface of the first electrode due to the rotational torque.

FIG. 10 is a cross-sectional view of an ultra-thin LED element according to an embodiment of the present disclosure.

FIG. 11 is a mimetic diagram of a light source according to an embodiment of the present disclosure.

FIG. 12 and FIG. 13 are mimetic diagrams of light sources according to various embodiments of the present disclosure.

FIG. 14 to FIG. 18 are SEM photographs taken after step S3 in the manufacturing process of an ultra-thin LED electrode assembly according to various embodiments of the present disclosure.

FIG. 19 is a photograph of the light emitted after a 5 V direct current driving power source was applied to the ultra-thin LED electrode assembly according to Example 1.

### DETAILED DESCRIPTION OF THE EMBODIMENTS

Hereinafter, with reference to the attached drawings, embodiments of the present disclosure will be described in detail so that those skilled in the art can easily practice the present disclosure. The present disclosure may be implemented in various different forms and is not limited to the embodiments described herein.

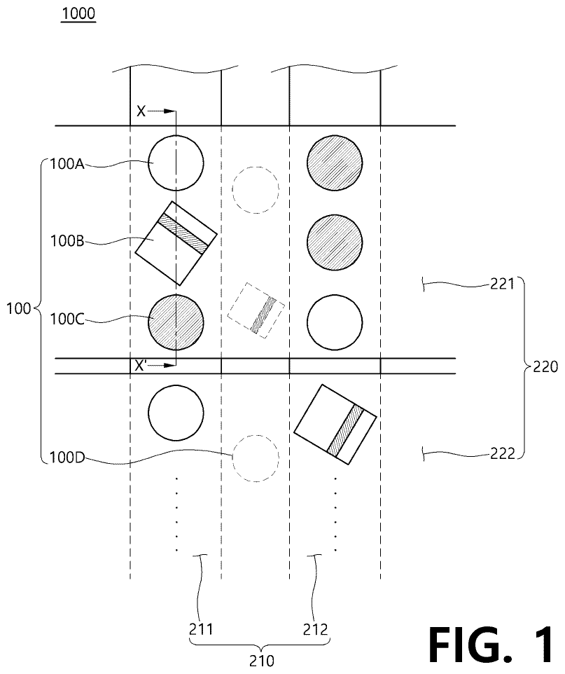

Referring to FIGS. 1 to 3, an ultra-thin LED electrode assembly 1000 according to one embodiment of the present disclosure includes a first electrode line 210 with at least two first electrodes 211, 212 having upper surfaces spaced apart from each other such that they face each other on a side surface, a plurality of ultra-thin LED elements 100 and a second electrode line 220 arranged on the ultra-thin LED elements 100.

According to one embodiment of the present disclosure, the ultra-thin LED electrode assembly 1000 may be manufactured by including the steps of injecting a solution in which a plurality of ultra-thin LED elements 100 are provided on a first electrode line 210 in which at least two first electrodes 211, 212 having upper surfaces are spaced apart from each other such that side surfaces thereof are opposite to each other (step S1), applying power having a frequency of 500 Hz or less to adjacent first electrodes 211, 212 to form an electric field (step S2), moving the ultra-thin LED elements 100 located within the electric field into upper surfaces of the first electrodes 211, 212 (step S3), and forming a second electrode line 220 on the ultra-thin LED elements 100A, 100B, 100C arranged within the upper surfaces of the first electrodes 211, 212 (step S4).

First of all, a step of injecting a solution including ultra-thin LED elements 100 onto a first electrode line 210 including at least two first electrodes 211, 212 in step S1 will be described.

The first electrode line 210 includes at least two first electrodes 211, 212.

The first electrodes 211, 212 provides upper surfaces that become mounting surfaces on which the ultra-thin LED elements 100 injected onto the first electrode line 210 are mounted. The upper surfaces may be exposed surfaces of the first electrodes 211, 212 that are substantially parallel to a surface of a base substrate 300 on which the first electrodes 211, 212 are formed.

In addition, the first electrodes 211, 212 perform the function of forming an electric field that is capable of moving and aligning the ultra-thin LED elements 100 during the manufacturing process of the ultra-thin LED electrode assembly. To this end, at least two of the first electrodes 211, 212 are formed to be spaced apart from each other such that an electric field is formed by the applied power. In addition, the first electrodes 211, 212 may function as driving electrodes for emitting light from the ultra-thin LED elements 100 together with the second electrodes 221, 222 in the implemented ultra-thin LED electrode assembly 1000. In other words, since the same type of power is applied to the first electrodes 211, 212 during operation, even if the interval between the first electrodes 211, 212 is designed narrowly, there is less concern about an electrical short circuit when operating the ultra-thin LED electrode assembly 1000. On the other hand, when manufacturing the ultra-thin LED electrode assembly 1000, a large electric field may be formed, which is advantageous for the movement and alignment of the ultra-thin LED element 100 that is inserted, and the design restrictions on the interval between the first electrodes are reduced, and thus, there is an advantage in that the design of the first electrode line 210 is easy.

Meanwhile, the specific circuit design of the first electrode line 210 in which the first electrodes 211, 212 are designed to perform the above function may be achieved by appropriately adopting and modifying a technology for circuit design known in the light source field, and thus, the present disclosure is not particularly limited thereto. In addition, the number, thickness, width, shape and arrangement of the first electrodes 211, 212 may adopt a known light source electrode line or may be appropriately changed according to the purpose, and thus, the present disclosure is not particularly limited thereto. For example, the first electrodes 211, 212 may be aluminum, chromium, gold, silver, copper, graphene, ITO or an alloy thereof, and may have a width of 2 to 50 μm and a thickness of 0.1 to 100 μm.

In addition, the first electrodes 211, 212 may be formed on a base substrate 300. The base substrate 300 may function as a support for supporting an ultra-thin LED electrode assembly. The base substrate 300 may be a known substrate used for a light source such as a display, and the present disclosure is not particularly limited in terms of the material, area, thickness and the like of the base substrate 300. For example, the base substrate 300 may be any one selected from the group consisting of glass, plastic, ceramic and metal, but is not limited thereto. In addition, the base substrate 300 may preferably be made of a transparent material in order to minimize the loss of light emitted from the ultra-thin LED elements 100. In addition, the base substrate 300 may be, for example, a flexible material. In addition, the size and thickness of the base substrate 300 may be appropriately changed in consideration of the size and number of ultra-thin LED elements provided, the specific design of the first electrode line 210 and the like, and therefore, the present disclosure is not particularly limited thereto.

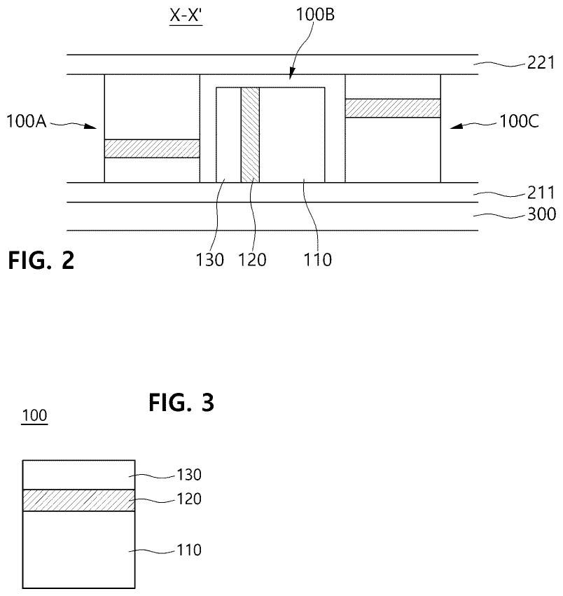

Meanwhile, unlike that illustrated in FIG. 2, the first electrode line 210 may be formed on a passivation layer having a flat surface instead of the base substrate 300, and a known circuit component such as a thin film transistor may be arranged under the passivation layer.

In addition, the solution having a plurality of ultra-thin LED elements 100 injected onto the first electrode line 210 described above includes the ultra-thin LED element 100 and a solvent.

The ultra-thin LED elements 100 may be known LED elements used in a light source. The ultra-thin LED elements 100 may include a first conductive semiconductor layer 110, a second conductive semiconductor layer 130 and a photoactive layer 120 disposed between the first conductive semiconductor layer 110 and the second conductive semiconductor layer 130 in a direction in which the layers are stacked.

In addition, any one of the first conductive semiconductor layer 110 and the second conductive semiconductor layer 130 may include at least one n-type semiconductor layer, and the other conductive semiconductor layer may include at least one p-type semiconductor layer. In addition, the direction in which a plurality of layers are stacked is defined as a thickness direction of the ultra-thin LED element 100, and the surfaces of the ultra-thin LED elements 100 facing each other in the thickness direction are referred to as a first surface and a second surface, respectively, and are described below. For example, in the case of an ultra-thin LED element composed of a first conductive semiconductor layer 110, a photoactive layer 120 and a second conductive semiconductor layer 130, the first surface is one surface of the first conductive semiconductor layer 110 or the second conductive semiconductor layer 130, and the second surface is one surface of the second conductive semiconductor layer 130 or the first conductive semiconductor layer 110.

When the first conductive semiconductor layer 110 includes an n-type semiconductor layer, the n-type semiconductor layer may be selected from at least any one semiconductor material having a composition formula of InₓAl_{y}Ga_{1-x-y}N (0≤x≤1, 0≤y≤1, 0≤x+y≤1), such as InAlGaN, GaN, AlGaN, InGaN, AlN, InN and the like, and may be doped with a first conductive dopant (e.g., Si, Ge, Sn, etc.). According to a preferred embodiment of the present disclosure, the thickness of the first conductive semiconductor layer 110 including the n-type semiconductor layer may be 0.2 to 3 μm, but is not limited thereto.

In addition, when the second conductive semiconductor layer 130 includes a p-type semiconductor layer, the p-type semiconductor layer may be selected from at least any one of semiconductor materials having a composition formula of InₓAl_{y}Ga_{1-x-y}N (0≤x≤1, 0≤y≤1, 0≤x+y≤1), such as InAlGaN, GaN, AlGaN, InGaN, AlN, InN and the like, and may be doped with a second conductive dopant (e.g., Mg). According to a preferred embodiment of the present disclosure, the thickness of the second conductive semiconductor layer 130 including the p-type semiconductor layer may be 0.01 to 0.35 μm, but is not limited thereto.

Next, the photoactive layer 120 is formed between the first conductive semiconductor layer 110 and the second conductive semiconductor layer 130, and may be formed as a single or multiple quantum well structures. The photoactive layer 120 above may be used without limitation as a photoactive layer included in a typical LED element used for lighting, display and the like. A cladding layer (not shown) doped with a conductive dopant may be formed above and/or below the photoactive layer 120, and the cladding layer doped with a conductive dopant may be implemented as an AlGaN layer or an InAlGaN layer. In addition, materials such as AlGaN and AlInGaN may also be used as the photoactive layer 120. When an electric field is applied to the element, electrons and holes move from the conductive semiconductor layers located above and below the photoactive layer to the photoactive layer, and electron-hole pair combinations occur in the photoactive layer, thereby emitting light. According to a preferred embodiment of the present disclosure, the thickness of the photoactive layer 120 may be 30 to 300 nm, but is not limited thereto.

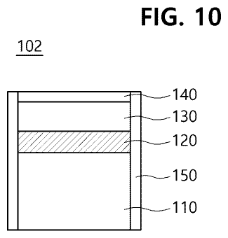

In addition, the ultra-thin LED element 100 is illustrated as including a first conductive semiconductor layer 110, a photoactive layer 120 and a second conductive semiconductor layer 130 as minimum components, but it is disclosed that other active layers, conductive semiconductor layers, fluorescent layers, hole blocking layers and/or electrode layers may be further included above/below each layer. For example, as illustrated in FIG. 10, an electrode layer 140 may be further included. The electrode layer 140 may be a typical electrode layer provided in an LED element without limitation, and non-limiting examples thereof include, but are not limited to, materials such as Cr, Ti, Al, Au, Ni, ZnO, AZO, ITO and oxides or alloys thereof, alone or in combination. In addition, the thickness of the electrode layer 140 may be 10 to 500 nm, but is not limited thereto.

In addition, the shape of the cross-section perpendicular to a direction in which the layers of the ultra-thin LED elements 100 are stacked is depicted as a circle, but is not limited thereto, and it is disclosed that the cross-sectional shape of the ultra-thin LED element may be adopted without limitation from a general polygonal shape such as a square, a rectangle, a rhombus, a parallelogram or a trapezoid to an oval and the like.

In addition, the size of the ultra-thin LED elements 100 may have a nano or micro scale size that makes it difficult to mount the LED elements using the pick-and-place technology. For example, the thickness, which is the length in a direction in which the layers of the ultra-thin LED element are stacked, may be, for example, 0.5 to 1.5 μm. In addition, the size of the cross-section perpendicular to a direction in which the layers are stacked may be defined differently depending on the shape, but for example, if the shape of the cross-section is a non-polygon such as a circle or an ellipse, it may be the diameter having the longest length among the line segments crossing the cross-section border, and the diameter may be 0.5 to 3.0 μm. In addition, when the cross-section is polygonal, the length of one side may be 0.5 to 3.0 μm.

The above-described ultra-thin LED elements 100 are injected onto the first electrode line 210 in a solution state of being dispersed in a solvent, and in this case, the solvent has the function of a dispersion medium that disperses the ultra-thin LED element s100. The solvent may be any solvent that does not physically and chemically damage the ultra-thin LED elements 100 and preferably increases the dispersibility of the ultra-thin LED elements 100 without limitation. For example, the solvent may be one or a mixture of two or more solvents such as acetone, isopropyl alcohol, ethanol, polyethylene glycol, propylene glycol methyl ether acetate (PGMEA), hexane and dodecane.

In addition, the solution including the ultra-thin LED elements 100 may be injected onto the first electrode line 210 through a known method. For example, the solution may utilize a known device that discharges a solution, such as a printing device such as an inkjet printer, a spraying device or a discharge device such as a dispenser. In addition, the solution including the ultra-thin LED elements 100 that is suitable for each discharge device may be implemented as ink or paste, and the type of solvent may be appropriately selected in consideration of the required viscosity and other physical properties. Meanwhile, the injection method for each discharge device may be based on a known method for each discharge device, and the present disclosure is not particularly limited thereto. In addition, the solution may further include an additive such as a dispersant that is typically added to the ink or paste used for the corresponding discharge device. In addition, the solution containing the ultra-thin LED elements may contain the ultra-thin LED elements in an amount of 0.01 to 99.99 wt % in the solution, and the present disclosure is not particularly limited thereto.

Meanwhile, on the first electrode line 210 described above, a partition wall (not shown) formed of a side wall surrounding the target area at a certain height may be further included to prevent the injected ultra-thin LED elements 100 from flowing to a part other than the target area and to concentrate and arrange the ultra-thin LED elements 100 on the target area, and a solution including the ultra-thin LED elements 100 may be injected into the partition wall. The partition wall may be formed of an insulating material so as not to cause an electrical influence when the ultra-thin LED element 100 is driven in the final ultra-thin LED electrode assembly 1000 in which the ultra-thin LED element 100 is mounted. Preferably, the insulating material may be at least any one of inorganic insulators such as silicon dioxide (SiO₂), silicon nitride (Si₃N₄), aluminum oxide (Al₂O₃), hafnium oxide (HfO₂), yttrium oxide (Y₂O₃) and titanium dioxide (TiO₂), and various transparent polymer insulators. In addition, the partition wall may be manufactured by patterning and etching processes such that the insulating material is formed on the first electrode line 210 to a certain height and then becomes a side wall surrounding the desired area.

In this case, if the material of the partition wall is an inorganic insulator, the partition wall may be formed by any one method of chemical vapor deposition, atomic layer deposition, vacuum deposition, e-beam deposition and spin coating. In addition, if the material is a polymer insulator, the partition wall may be formed by using a coating method such as spin coating, spray coating and screen printing. In addition, the patterning may be formed through photolithography using a photosensitive material, or may be formed by a known nanoimprinting method, laser interference lithography, electron beam lithography and the like. In this case, the height of the formed partition wall is at least ½ of the thickness of the ultra-thin LED element 100, and is typically a thickness that may not affect the post-process after self-alignment, and may be preferably 0.1 to 100 μm, and more preferably, 0.3 to 10 μm. If the above range is not satisfied, the post-process may be affected, thereby making it difficult to manufacture the ultra-thin LED electrode assembly, and particularly, if the height of the partition is excessively low compared to the thickness of the ultra-thin LED element 100, the solution including the ultra-thin LED element 100 may overflow out of the partition, thereby making it difficult to perform the function of the partition wall.

In addition, when manufacturing the partition wall, the etching may adopt an appropriate etching method considering the material of the insulator, and for example, it may be performed through a wet etching method or a dry etching method, and preferably, it may be performed by any one or more dry etching methods among plasma etching, sputter etching, reactive ion etching and reactive ion beam etching.

Meanwhile, the S1 step has been described as the ultra-thin LED elements 100 being introduced in a solution state mixed with a solvent, but it should be noted that in cases where the ultra-thin LED elements 100 are first injected onto the first electrode line 210 and then the solvent is injected, or conversely, where the solvent is first injected and then the ultra-thin LED elements 100 are injected, the same result as when the solution is injected is also included in the S1 step.

Next, the method for manufacturing an ultra-thin LED electrode assembly 1000 according to an embodiment of the present disclosure includes a step (step S2) of applying power having a frequency of 500 Hz or less to adjacent first electrodes 211, 212 to form an electric field. Step S2 may be performed before, simultaneously with, or after step S1 described above. That is, the power applied to the first electrode 211, 212 may be applied before, simultaneously with, or after a solution including an ultra-thin LED element 100 is applied onto the first electrode 211, 212, and the present disclosure does not specifically limit the timing of applying the power applied to the first electrode 211, 212.

Step S2 is a step of applying power having a frequency of 500 Hz or less to the first electrode 211, 212, and the electric field formed by the application of the power exerts a force that moves and aligns the ultra-thin LED elements 100 on the upper surface of the first electrodes 211, 212. Hereinafter, the force will be described first.

The electric field formed by the power having a frequency of 500 Hz or less applied to the first electrodes 211, 212 may independently move and align the ultra-thin LED elements 100 to be positioned on the upper surface of any one of the first electrodes 211, 212. This movement and alignment behavior is a result of the electro-osmotic pressure being dominant among the various forces applied to the ultra-thin LED elements 100, and is different from the self-alignment of the LED elements when the dielectrophoretic force, which competes with the electro-osmotic pressure, becomes dominant.

Specifically, when the mechanism of dielectrophoresis is first explained, dielectrophoresis refers to a phenomenon in which a directional force is applied to a particle due to a dipole induced in the particle when the particle is placed in a non-uniform electric field. In this case, the strength of the force may vary depending on the electrical properties of the particle and the medium, the dielectric properties, the frequency of the AC electric field and the like, and the average force (FDEP) received by the particle during dielectrophoresis is as follows in Mathematical Expression 1.

$$[ Mathematical Expression 1 ]$$

$${F}_{DEP} = 2 π {r}^{3} {ε}_{m} Re [ K ( ω ) ] ∇ {\vert E \vert}^{2}$$

In Mathematical Expression 1, r, εₘ and E represent the radius of the particle, the permittivity of the medium, and the root mean square magnitude of the applied AC electric field, respectively. In addition, Re[K(ω)] is a factor that determines a direction in which a particle close to a sphere moves, and means the real part of the value according to Mathematical Expression 2 below.

$$[ Mathematical Expression 2 ]$$

$$K ( ω ) = \frac{{ε}_{p}^{*} - {ε}_{m}^{*}}{{ε}_{p}^{*} + 2 {ε}_{m}^{*}}$$

Herein, εₚ* and εₘ* are the complex permittivity of the particle and the medium, respectively, and ε* is given by t Mathematical Expression 3 below.

$$[ Mathematical Expression 3 ]$$

$${ε}^{*} = ε - j \frac{σ}{ω}$$

Herein, σ represents the electrical conductivity, ε represents the dielectric constant, ω represents the angular frequency (ω=2πf), and j represents the imaginary part (i=\sqrt{−1}).

In this case, the movement of the particle during dielectrophoresis is largely dependent on a change in the factor according to Mathematical Expression 2, and specifically, the movement of the particle located under the electric field may be determined by a change in the sign of Re[K(ω)] according to the frequency of the applied power. For example, if Re[K(ω)] has a positive value, the particle moves toward the high electric field region, that is, the two electrodes that formed the electric field, and this is called positive dielectrophoresis (positive DEP, p-DEP). In addition, if Re[K(ω)] has a negative value, the particle may move away from the high electric field region, that is, away from the two electrodes that formed the electric field, and this is called negative DEP (negative DEP, n-DEP).

This mechanism of dielectrophoresis is equally applied to an ultra-thin LED element 100 positioned together with a solvent as a medium on two electrodes forming an electric field.

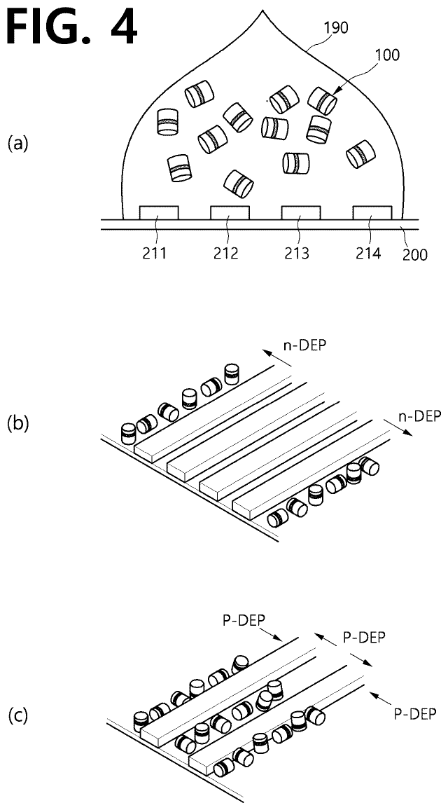

Referring to FIG. 4, when different powers are applied to first electrodes 211, 212, 213, 214 that are spaced apart from each other, ultra-thin LED elements 100 positioned in a mixed state in a solvent 190 within an electric field formed by applying different powers may be subjected to a negative dielectrophoretic force (n-DEP) or a positive dielectrophoretic force (p-DEP) depending on the size of the electric field, frequency, dielectric constant of the solvent 190, shape of the ultra-thin LED element and element material in the state (a) of FIG. 4. If a negative dielectrophoretic force (n-DEP) is applied to the ultra-thin LED elements 100, the ultra-thin LED elements 100 move away from a region where the electric field is formed, as shown in FIG. 4 (b), and are aligned on the outside of the outermost first electrodes 211, 214. Alternatively, if a positive dielectrophoretic force (p-DEP) is applied to the ultra-thin LED elements 100 in the state (a) of FIG. 4, the ultra-thin LED elements 100 move and align between the two adjacent first electrodes 211, 212, 213 where the highest electric field is formed, as shown in (c) of FIG. 4.

In this case, the ultra-thin LED elements 100 moved and aligned as shown in (b) of FIG. 4 are aligned on a side away from the first electrode 211, 214, and thus, the ultra-thin LED elements may not move and be mounted on the upper surface of the first electrode. In addition, even in the case of the ultra-thin LED elements 100 moved and aligned as shown in (c) of FIG. 4, the ultra-thin LED elements may not move and be mounted on the upper surface of the first electrode. Furthermore, in neither of (b) of FIG. 4 nor (c) of FIG. 4, the ultra-thin LED elements are drivable. However, as can be confirmed in (c) of FIG. 4, when using a positive dielectrophoretic force, the LED elements may be aligned to move between two adjacent electrodes and simultaneously sit on the upper surfaces of the two adjacent electrodes. Therefore, there is room to change the design such that the LED elements may be aligned over the two adjacent first electrodes 211, 212, 213 under the limited condition of increasing the length of the LED element such that a larger positive dielectrophoretic force is applied, and adjusting the interval between the first electrodes 211, 212, 213 to be smaller than the length of the LED element.

Therefore, in neither case can the LED elements be moved or aligned within the upper surface of either of the two adjacent first electrodes that formed the electric field by using a positive dielectrophoretic force or a negative dielectrophoretic force. In addition, when the shape of the LED element has a small aspect ratio, the positive dielectrophoretic force applied to the LED element is not large such that self-alignment may not occur smoothly even if the size of the LED element and the interval between the first electrodes are adjusted.

Accordingly, the inventor of the present disclosure continued to study the movement and self-alignment mechanism of the LED elements on two electrodes where an electric field is formed, and when the frequency of the applied power is adjusted, the electro-osmotic pressure becomes the dominant force applied to the ultra-thin LED elements, and thus, it was found that the self-alignment of the LED elements by the positive dielectrophoretic force under the electric field, which was previously known, can be performed in a different form, that is, the LED elements can move and align within the upper surface of one of the two adjacent electrodes where the electric field is formed, thereby leading to the present disclosure.

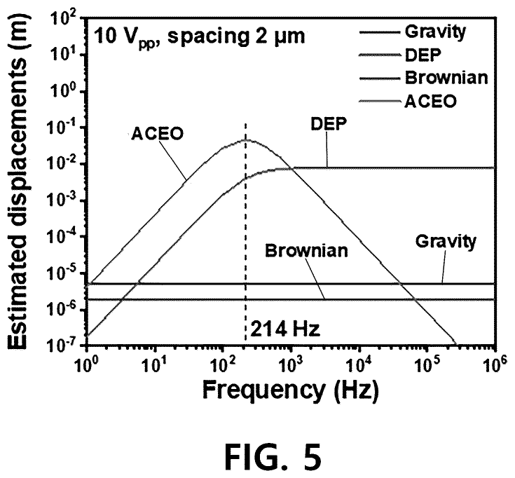

Specifically, when an electric field is applied to the ultra-thin LED elements, the forces applied to the ultra-thin LED elements are gravity, Brownian motion force, dielectrophoretic force and electro-osmotic pressure force. When this is explained by referring to FIG. 5, when the distance that the ultra-thin LED elements move is simulated by using the frequency of the electric field applied as a variable, the distance that the ultra-thin LED elements move by gravity and Brownian motion force hardly changes depending on the frequency of the electric field. On the other hand, the distance that the ultra-thin LED elements move varies depending on the frequency of the electric field due to the electro-osmotic pressure and dielectrophoretic force, and depending on the frequency, the ultra-thin LED elements to which the electro-osmotic pressure is predominantly applied move above any one of the two adjacent first electrodes that form the electric field, and the ultra-thin LED elements to which the dielectrophoretic force are predominantly applied moves between the two adjacent first electrodes, and these two forces may compete.

Specifically, as shown in FIG. 5, a cylindrical ultra-thin LED element having a thickness of 1.05 μm, which is the length in a direction in which the layers are stacked, a surface diameter of 750 nm perpendicular to a direction in which the layers are stacked, and including an n-type conductive semiconductor layer, a photoactive layer and a p-type conductive semiconductor layer, has a distance between adjacent first electrodes of 2 μm, an applied power intensity of 10 Vpp, and a solvent of acetone, and when the frequency of the power applied to the first electrode is 1 kHz or less, the electro-osmotic pressure becomes the most dominant force applied to the ultra-thin LED element, and when the frequency exceeds 1 kHz, the dielectrophoretic force becomes the most dominant force applied to the ultra-thin LED element. As a result, when the frequency of the applied power is 1 kHz or less, it is more advantageous to move and align the ultra-thin LED element on the upper surface of the first electrode.

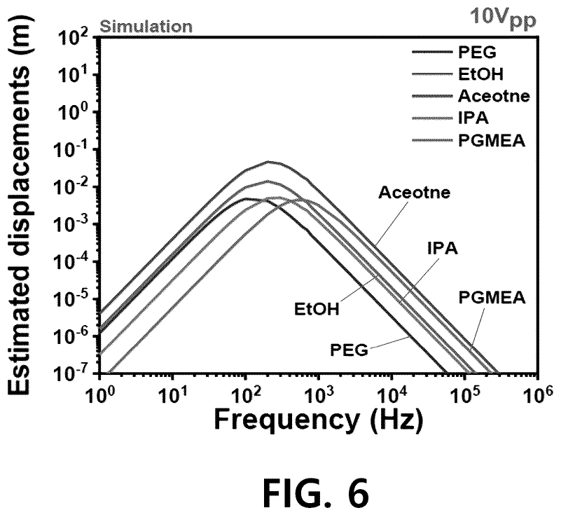

In addition, as shown in FIG. 6, depending on the type of solvent that moves the ultra-thin LED elements, the frequency at which the dominant force applied to the ultra-thin LED elements becomes the electro-osmotic pressure may vary. However, even though the frequency at which the electro-osmotic pressure is maximum may vary depending on the specific type of solvent, it can be seen that the electro-osmotic pressure may still become the dominant force at frequencies below 1 kHz, especially below 500 Hz, because the electro-osmotic pressure is maximum at frequencies below 1 kHz, especially below 500 Hz.

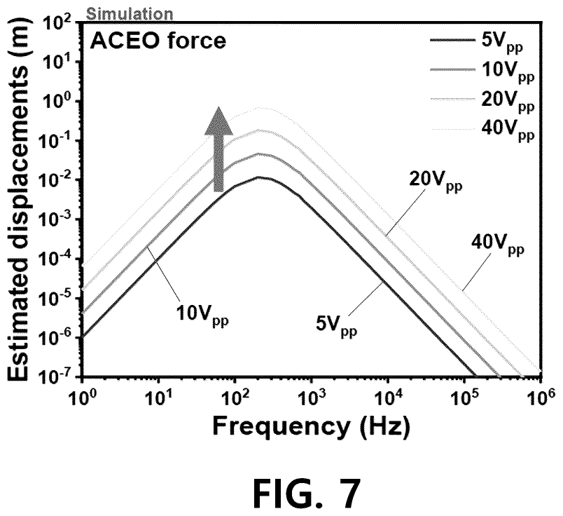

However, as shown in FIG. 7, when the voltage of the power supply is increased, the distance at which the ultra-thin LED elements move by the electro-osmotic pressure increases, but even if the voltage changes, the frequency at which the electro-osmotic pressure is maximum remains the same at 1 kHz, especially below 500 Hz, and it can be seen that even if the voltage increases, the force applied to the ultra-thin LED element does not shift from a region where the electro-osmotic pressure is dominant to a region where the dielectrophoretic force is dominant.

Accordingly, the method for manufacturing an ultra-thin LED electrode assembly 1000 according to an embodiment of the present disclosure includes applying power having a frequency of 500 Hz or less to the first electrodes 211, 212 such that the dominant force applied to the ultra-thin LED elements 100 to be positioned within an electric field formed by two adjacent first electrodes 211, 212 becomes an electro-osmotic pressure (step S2). If the frequency of the applied power exceeds 500 Hz, the force applied to the ultra-thin LED elements 100 competes with the dielectrophoretic force, and if the frequency increases further, the dielectrophoretic force becomes the dominant force, and thus, the ratio of the ultra-thin LED elements positioned on the upper surface of the first electrode relative to the number of ultra-thin LED elements introduced may be significantly reduced. Accordingly, preferably, the power applied to the first electrode 211, 212 may be 1 Hz to 500 Hz and the voltage may be 5 to 100 Vpp, more preferably, the frequency may be 1 to 50 Hz and the voltage may be 5 to 80 Vpp, even more preferably, the frequency may be 1 to 30 Hz and the voltage may be 5 to 50 Vpp, and more preferably, the frequency may be 5 to 20 Hz and the voltage may be 5 to 40 Vpp, thereby preventing or minimizing damage to the first electrode while efficiently moving and aligning the ultra-thin LED element within the upper surface of the first electrode. If the voltage exceeds 100 Vpp, damage to the first electrode may occur, which may cause a short circuit of the first electrode during the execution of step S3, thereby stopping the movement and alignment of the ultra-thin LED element, or the damage may be so severe that the ultra-thin LED element may not emit light smoothly when it is driven. In addition, if the voltage is less than 1 Vpp, there is a concern that the ratio of the ultra-thin LED elements settled into the upper surface of the first electrode may be greatly reduced.

In addition, according to one embodiment of the present disclosure, in order to increase the dominance of the electro-osmotic pressure for the ultra-thin LED elements 100 and increase the ratio of the ultra-thin LED elements moved and aligned into the upper surface of each of the first electrodes 211, 212, the viscosity of the solvent 190 in which the ultra-thin LED elements 100 are dispersed in step S1 may be 50 cP or less, and more preferably, 5 to 15 cP. If the viscosity of the solvent exceeds 50 cP, there is a concern that the ratio of the number of ultra-thin LED elements moved and aligned into the upper surface may not be sufficient compared to the number of ultra-thin LED elements injected. In addition, if the viscosity is less than 5 cP, the speed of volatilization is fast such that the solvent is insufficient or does not exist in the middle of the movement and alignment of the ultra-thin LED elements, thereby making it difficult to secure sufficient process time required for movement and alignment. In this case, the viscosity is the viscosity measured at 25° C. using a Brookfield viscometer, and the specific measurement method is a known method, and thus, the present disclosure omits a specific description thereof.

Next, as step S3, moving the ultra-thin LED elements 100 located in the electric field to the upper surface of each of the first electrodes 211, 212 is performed.

As described above, the electric field formed by the applied power with the frequency appropriately adjusted may move the ultra-thin LED elements 100 to the upper surface of the first electrode 211, 212.

Specifically, when steps S1 to S3 are performed under appropriate conditions according to the present disclosure, the settling ratio according to Mathematical Formula 1, which corresponds to the ratio of the number of first ultra-thin LED elements 100A, 100B, 100C, which are ultra-thin LED elements disposed within the upper surface of the first electrode 211, 212, among the total number of ultra-thin LED elements 100 introduced in step S1, may be 40% or more, preferably, 50% or more, more preferably, 60% or more, 65% or more, 75% or more, 80% or more, 85% or more, 89% or more, or 95% or more.

$$[ Mathematical Formula 1 ]$$

$$First electrode upper surface settling ratio ( \% ) = \frac{Number of first ultra - thin LED elements}{Total number of ultra - thin LED elements} \times 100$$

Herein, the number of ultra-thin LED elements refers to a total number of ultra-thin LED elements placed within a unit area (1 mm²) of the first electrode line and a number of first ultra-thin LED elements. In addition, the present disclosure defines that the first ultra-thin LED elements 100A, 100B, 100C positioned within the upper surfaces of the first electrodes 211, 212 are ultra-thin LED elements in which 50% or more of the total contact surface area of the ultra-thin LED elements contacting the upper surface of the first electrodes 211, 212 is in contact with the upper surface of the first electrodes 211, 212. In addition, even if the interval between two adjacent first electrodes 211, 212 is narrow and one ultra-thin LED element contacts both upper surfaces of the first electrodes 211, 212, it is considered to belong to the first ultra-thin LED element.

Meanwhile, the ultra-thin LED elements 100 introduced in step S1 after going through the S3 step includes first ultra-thin LED elements 100A, 100B, 100C arranged on the upper surfaces of the first electrodes 211, 212 as shown in FIG. 1, and in some cases, it may include a second ultra-thin LED element 100D that is not positioned within the upper surface of the first electrodes 211, 212 but is positioned in the space between adjacent first electrodes 211, 212 or is positioned such that it contacts only any one of the first electrodes 211, 212 but the area of the contact surface is less than 50% of the area of one surface of the ultra-thin LED element that is in contact.

In addition, the first ultra-thin LED elements 100A, 100B, 100C may be mounted in various forms on the electrode surfaces of the first electrodes 211, 212. For example, the first ultra-thin LED elements 100A, 100B, 100C include a first conductive semiconductor layer 110, a photoactive layer 120 and a second conductive semiconductor layer 130 that form the first ultra-thin LED elements 100A, 100B, 100C and are formed on opposite first and second surfaces in the thickness direction, and they may be composed of a third ultra-thin LED element 100C mounted so that the first surface on a side of the first conductive semiconductor layer 110 contacts the upper surface of the first electrode 211, a fourth ultra-thin LED element 100A mounted so that the second surface on a side of the second conductive semiconductor layer 130 contacts the upper surface of the first electrode 211, and a fifth ultra-thin LED element 100B mounted so that a side relative to the thickness direction contacts the upper surface of the first electrode 211. In this case, among the mounting forms of the first ultra-thin LED elements 100A, 100B, 100C, the fifth ultra-thin LED element 100B does not emit light even when the second electrodes 221, 222 are formed on the first ultra-thin LED elements 100A, 100B, 100C through the S4 step described below. Accordingly, even if the ultra-thin LED element 100 is moved and aligned to the upper surface of the first electrodes 211, 212 through electro-osmotic pressure, there is a concern that the drivable mounting ratio, which is the ratio of ultra-thin LED elements that can be mounted so as to be driven, that is, it may emit light when driving power is applied, may not be sufficiently large.

As such, according to one embodiment of the present disclosure, the material or structure of the ultra-thin LED elements 100 introduced in the S1 step described above, the solvent 190 introduced therewith and the frequency and voltage of the power applied in the S2 step may be appropriately controlled such that the drivable mounting ratio, which is the total ratio of the number of the third ultra-thin LED elements 100C and the fourth ultra-thin LED elements 100A that are mounted so as to be drivable among the total number of the first ultra-thin LED elements 100A, 100B, 100C arranged within the upper surface of the first electrode 211, 212 within the unit area (1 mm²) of the first electrode line, is high.

First of all, the solvent 190 may have a dielectric constant of 5 or more, more preferably, 14 or more, more preferably, 23 or more, and more preferably, 33 or more, in order to increase the ratio of movement and settling of the ultra-thin LED elements 100 into the upper surface of the first electrode 211, 212 while simultaneously increasing the drivable mounting ratio. If the dielectric constant of the solvent is less than 5, the ratio of the ultra-thin LED elements moving and settling into the upper surface of the first electrode may decrease, or even if the ratio of the ultra-thin LED elements moving and settling into the upper surface of the first electrode is high, the ratio of the fifth ultra-thin LED elements (100B) among these ultra-thin LED elements, in which the side surface of the ultra-thin LED elements contacts the upper surface and does not emit light, may significantly increase, and thus, the luminance of the ultra-thin LED electrode assembly may be low. In addition, the solvent 190 may have, for example, a dielectric constant of 50 or less, and if the dielectric constant of the solvent exceeds 50, the ratio of the ultra-thin LED element moving and settling into the upper surface of the first electrode or the drivable mounting ratio may decrease, and there is a concern that the electrode may be damaged.

Next, the ultra-thin LED elements 100 may be materially/structurally modified such that the surface properties of the surfaces forming the ultra-thin LED elements differ between surfaces in order to increase the ratio of the ultra-thin LED elements moving and settling into the upper surface of the first electrodes 211, 212 while simultaneously increasing the drivable mounting ratio.

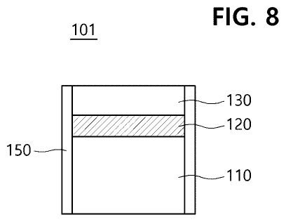

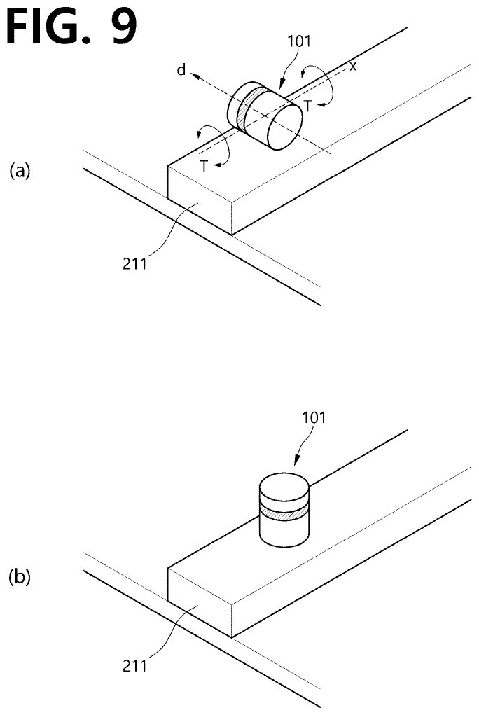

For example, the ultra-thin LED element 101 may further include a rotation-inducing film 150 surrounding the side surface as illustrated in FIG. 8, and through this, a difference in the physical properties through the material may be induced between the side surface and the upper/lower surface of the ultra-thin LED element 101. The difference in physical properties due to the difference in material between the side surface and the upper/lower surface may generate a rotational torque (T) in the ultra-thin LED element 101 based on the x-axis direction perpendicular to a direction (d) in which layers forming the ultra-thin LED element 101 are stacked under an electric field, as illustrated in FIG. 9. Accordingly, the ultra-thin LED element 101 having the rotation-inducing film 150 on the side surface may be moved on the upper surface of the first electrode 211 by electro-osmotic pressure and then rotated in the x-axis direction such that the mounting ratio of the actual surface contact between the upper surface and the lower surface, rather than the side surface, can be increased. Preferably, the rotation-inducing film 150 may have a dielectric constant (ε) of 30 or less, more preferably, 7 or less, and even more preferably, 5.5 or less, and as another example, it may be 3.0 or more, and through this, it is advantageous to increase the ratio (or number) of ultra-thin LED elements that move and settle on the upper surface of the first electrode, while increasing the drivable mounting ratio. If the dielectric constant of the rotation-inducing film exceeds 30, it may be difficult to increase the drivable mounting ratio because a sufficient torque may not be expressed.

In addition, the rotation-inducing film 150 may be used without limitation in the case of a material that has a difference in physical properties between the upper surface/lower surface of the ultra-thin LED element 101, and preferably, it may be a material that satisfies the dielectric constant condition described above. For example, the rotation-inducing film may be at least one material among HfO₂, ZrO₂, Al₂O₃, SiO₂ and SiNₓ, and as another example, it may be at least one material among Al₂O₃, SiO₂ and SiNₓ, and as still another example, it may be at least one material among SiO₂ and SiNₓ.

In addition, according to one embodiment of the present disclosure, the aspect ratio of the ultra-thin LED element may be controlled in order to increase the drivable mounting ratio. Specifically, the ultra-thin LED elements 100, 101, 102 may have a ratio (b/a) of the thickness (b), which is a length in the stacking direction, to the major axis length (a) in the cross-section perpendicular to the stacking direction of the layers, of more than 0 and less than 2.0. If the ratio of the thickness (b) to the major axis length (a) (b/a) exceeds 2.0, the side mounting ratio of the ultra-thin LED element may increase significantly, thereby decreasing the drivable mounting ratio, or the ratio of movement and settling into the electrode surface of the first electrode may decrease significantly. More preferably, the ratio of the thickness (b) to the major axis length (a) (b/a) may be more than 0 and less than 1.8, through which the drivable mounting ratio may be significantly improved, which may be advantageous in achieving the object of the present disclosure. Meanwhile, if the ratio of the thickness (b) to the major axis length (a) (b/a) decreases to more than 0 and less than 1.0, the ultra-small LED element mounted on the first electrode may have a higher probability of being mounted such that the first side or the second side comes into contact with the first electrode rather than the side due to a geometrical factor of the LED element.

Next, as step S4, a step of forming a second electrode line 220 on the ultra-thin LED elements arranged on the upper surface of the first electrode 211, 212, specifically, the first ultra-thin LED elements 100A, 100B, 100C, is performed.

The second electrode line 220 is not limited in number, arrangement, shape and the like, as long as it is designed to be in electrical contact with the upper portion of the first ultra-thin LED elements 100A, 100B, 100C arranged on the first electrode line 210 described above. However, as shown in FIG. 1, if the first electrode line 210 is arranged in a parallel manner in any one direction, each of the second electrodes 221, 222 constituting the second electrode line 220 may be arranged in a parallel manner in a direction perpendicular to the extension direction of the first electrodes 211, 212, and this electrode arrangement is an electrode arrangement widely used in conventional displays and the like, and has the advantage of being able to use the electrode arrangement and driving control technology of the conventional display field as it is.

Meanwhile, the second electrodes 221, 222 may have the material, shape, width and thickness of the electrode used in a conventional LED electrode assembly, and may be manufactured using a known method, and thus, the present disclosure does not specifically limit the same. For example, the second electrodes 221, 222 may be made of aluminum, chromium, gold, silver, copper, graphene, ITO or an alloy thereof, and may have a width of 2 to 50 μm and a thickness of 0.1 to 100 μm, but may be appropriately changed in consideration of the size of the desired LED electrode assembly, etc.

In addition, the second electrode line 220 may be implemented by patterning an electrode line using known photolithography and then depositing an electrode material, or by dry and/or wet etching the electrode material after deposition, and a description of the specific formation method is omitted.

Meanwhile, a step of forming a passivation layer on the first electrode line 210 on which the ultra-thin LED element 100 is arranged may be further included to fix and insulate each of the aligned first ultra-thin LED elements 100A, 100B, 100C in contact with the first electrode line 210 between the above-described steps S3 and S4, and to provide a surface on which the second electrodes 221, 222 formed in step S4 are formed. The passivation layer may be used without limitation as long as it is a passivation material commonly used in electrical and electronic components. For example, the passivation layer may be deposited using a passivation material such as SiO₂ or SiNₓ through a PECVD method, deposited using a passivation material such as AlN or GaN through a MOCVD method, or deposited using a passivation material such as Al₂O, HfO₂ or ZrO₂ through an ALD method. Meanwhile, the passive layer should be formed so as not to cover the upper surface of the self-aligned ultra-thin LED element 100, and to this end, the passive layer may be formed through deposition to a thickness that does not cover the upper surface, or the deposition may be performed so as to cover the upper surface, and then dry etching may be performed such that the upper surface of the ultra-thin LED element is exposed.

The ultra-thin LED electrode assembly 1000 implemented through the above-described manufacturing method includes a first electrode line 210 in which at least two first electrodes 211, 231 having upper surfaces are spaced apart from each other, an ultra-thin LED element 100 including first ultra-thin LED elements 100A, 100B, 100C each arranged so as to be positioned within the upper surface of any one first electrode 211, 212 and a second electrode line 220 arranged on the first ultra-thin LED elements 100A, 100B, 100C.

The first ultra-thin LED elements 100A, 100B, 100C may be mounted such that the drivable mounting ratio, which is the total number ratio of the third ultra-thin LED elements 100B and the fourth ultra-thin LED elements 100A, which are mounted such that the upper and lower surfaces of the first ultra-thin LED element 100A, 100B, 100C contact the first electrode 211, 212 and the second electrode 221, 222, is 40% or more, or in other examples, 45% or more, 50% or more, 60% or more, or 70% or more. Through this, the ultra-thin LED electrode assembly 1000 may increase the driving ratio and luminance of the mounted ultra-thin LED element 100.

In addition, the ultra-thin LED electrode assemblies 1000, 1000′ may have a unit area that is capable of independently driving the same, for example, 1 μm² to 100 cm², and more preferably 10 μm² to 100 mm², but is not limited thereto. In addition, the ultra-thin LED electrode assemblies 1000, 1000′ may include 2 to 100,000 ultra-thin LED elements 101 per unit area of 100×100 μm², but are not limited thereto.

Meanwhile, some of the first ultra-thin LED elements 100A, 100B, 100C provided in the ultra-thin LED electrode assembly 1000 illustrated in FIGS. 1 and 2 may include a fifth ultra-thin LED element 100C mounted such that a side surface thereof contacts the upper surface of the first electrodes 211, 212. If any one side surface of the fifth ultra-thin LED element 100C is mounted such that it contacts the upper surface of the first electrode 211 and the other side surface of the LED element also contacts the second electrode 221, 222, there is a concern that when the ultra-thin LED electrode assembly 1000 is operated, the fifth ultra-thin LED element 100C may cause an electrical short, thereby damaging or causing a short circuit in the first electrodes 211, 212 and the second electrodes 221, 222 and causing a current leak. As such, according to one embodiment of the present disclosure, the thickness of the ultra-thin LED element may be greater than the diameter of the cross-section of the element perpendicular to a direction in which the layers of the element are stacked, or the length of any line segment forming the cross-section, thereby preventing an electrical short circuit or leakage that may occur when the side surface of the ultra-thin LED element comes into contact with both the first electrode and the second electrode.

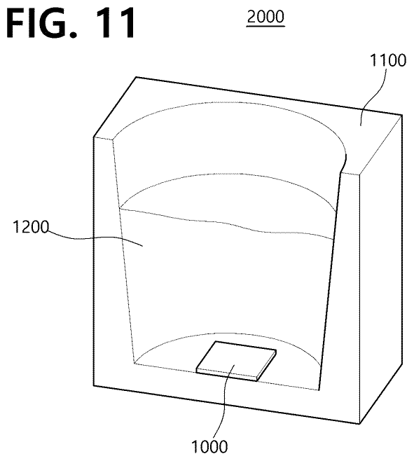

In addition, the ultra-thin LED electrode assemblies 1000, 1000′ according to one embodiment of the present disclosure described above may be applied to known light sources in which LED elements are employed. For example, when it is explained by referring to FIGS. 11 to 13, light sources 2000, 2000′, 3000 according to one embodiment of the present disclosure may be implemented by including supports 1100, 1100′, 1100″ and ultra-thin LED electrode assemblies 1000, 1001, 1002, 1003 provided on the supports 1100, 1100′, 1100″.

The above supports 1100, 1100′, 1100″ are for supporting ultra-thin LED electrode assemblies 1000, 1001, 1002, 1003, and may be used as supports without limitation regardless of the material if it they have a certain level of mechanical strength or higher for performing a support function, and as a non-limiting example thereof, it may be at least one material selected from the group consisting of organic resins, ceramics, metals and inorganic resins. In addition, the supports 1100, 1100′, 1100″ may be transparent or opaque.

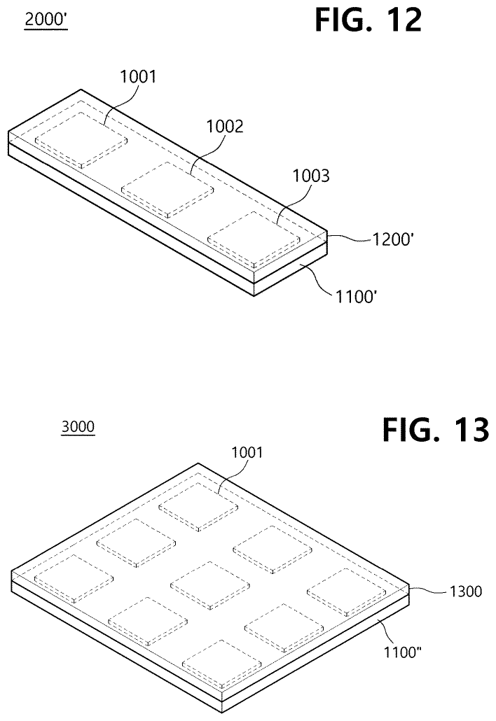

In addition, the shape of the supports 1100, 1100′, 1100″ may be a cup shape as illustrated in FIG. 12, or a plate shape as illustrated in FIGS. 12 and 13, but is not limited thereto, and may have various shapes depending on the shape of the surface on which the light source is mounted. In addition, the area and/or volume of the supports 1100, 1100′, 1100″ may also be appropriately adjusted in consideration of the luminance characteristics of the light source to be implemented, the number/arrangement structure of the ultra-thin LED electrode assemblies 1000, 1001, 1002, 1003 provided accordingly, and the use of the light source, and thus, the present disclosure is not particularly limited thereto. In addition, the thickness of the supports 1100, 1100′, 1100″ may be appropriately adopted to support the ultra-thin LED electrode assemblies 1000, 1001, 1002, 1003 by considering the strength of the material.

In addition, it is disclosed that the support 1100 illustrated in FIG. 11 may also serve as a housing for the light source in itself in addition to the function of supporting the ultra-thin LED electrode assemblies 1000. In addition, the ultra-thin LED electrode assemblies 1000, 1001, 1002, 1003 provided to the light source do not include the above-described base substrate on which the first electrode line 210 is formed when the supports 1100, 1100′, 1100″ are provided to the light source, and it is disclosed that the first electrode line 210 may be arranged on the supports 1100, 1100′, 1100″.

In addition, one or two more ultra-thin LED electrode assemblies 1000, 1001, 1002, 1003 may be provided in the light sources 2000, 2000′, 3000. In this case, the ultra-thin LED elements provided in a single ultra-thin electrode assembly 1000, 1001, 1002, 1003 may be configured as an element that substantially emits any color, and the light color may be, for example, any one of UV, blue, green, yellow, amber and red. Meanwhile, when two or more ultra-thin LED electrode assemblies 1001, 1002, 1003 are provided in the light sources 2000′, 3000 and they are configured to be driven independently, the light source may be implemented to emit various types of light colors, and such a light source may be employed in a display such as an LCD or OLED. In addition, when two or more ultra-thin LED electrode assemblies 1000, 1001, 1002, 1003 are included, their arrangement may be arranged in a linear manner in any one direction as shown in FIG. 12, or in a planar arrangement as shown in FIG. 13, or may be arranged randomly, unlike this.

In addition, the light sources 2000, 2000′, 3000 may further include a color conversion material such that the light emitted from the ultra-thin LED electrode assemblies 1000, 1001, 1002, 1003 has a specific wavelength. The color conversion material is excited by the light emitted from the ultra-thin LED element and performs the function of emitting light having a specific wavelength. For example, the color conversion material may be provided in a buried layer 1200 inside a receiving portion when the support 1100 has a cup shape and has a receiving portion inside as shown in FIG. 11, or may be provided in the form of coating layers 1200′, 1300 when the supports 1100′, 1100″ are flat as shown in FIG. 12 and FIG. 13.

In addition, the color conversion material may be determined by considering the light color emitted by the ultra-thin LED element. For example, in the case of an element emitting UV, the color conversion material may be at least one of blue, cyan, yellow, green, amber and red, and through this, it is possible to implement a monochromatic light source of any color or a white light source. As an example of implementing a white light source, in the case of an element emitting UV, the color conversion material may be a mixture of any one of blue/yellow, red/cyan, blue/green/red and blue/green/amber/red, and through this, it may implement a white light source. Additionally, in the case of an element that emits blue, the color conversion material may be at least any one of yellow, cyan, green, amber and red, and through this, it is possible to implement a single-color light source or a white light source. As an example of implementing the white light source, any two or more colors may be combined, and specifically, a white light source may be implemented by combining any one of blue/yellow, red/cyan, blue/green/red and blue/green/amber/red.

Meanwhile, the color conversion material may be a known fluorescent substance or quantum dot used in lighting, displays and the like, and the present disclosure is not particularly limited to the specific type thereof.

The above-described light sources 2000, 2000′, 3000 may be configured as an electric or electronic component or device by itself or in combination with another known configuration. For example, the known configuration may be an input section for receiving signals required for the operation of the ultra-thin LED electrode assemblies 1000, 1001, 1002, 1003, a heat dissipation section such as a heat sink for transferring heat generated when the ultra-thin LED electrode assemblies 1000, 1001, 1002, 1003 are operated to the outside, and a housing for packaging the light source with other components.

In addition, the light sources 2000, 2000′, 3000 may be employed in various electrical and electronic devices that require a light-emitting body, such as various LED lighting for home/vehicle use, displays, medical devices, beauty devices and various optical devices. Meanwhile, the medical device may be an optogenetic LED light source that, for example, emits light of a predetermined wavelength to the brain to activate neural networks of the corresponding area. The optogenetic LED light source may include multiple ultra-thin LED electrode assemblies on a support. In addition, the beauty device may be, for example, a skin care LED mask, and may be implemented to have multiple ultra-thin LED electrode assemblies on the inner surface of a mask support that comes into contact with the skin.

The present disclosure will be described in more detail through the following examples, but the following examples do not limit the scope of the present disclosure, and it should be interpreted that they are intended to help understand the present disclosure.

### Example 1

First of all, an ultra-thin LED element was prepared as follows. Specifically, a conventional LED wafer (Epistar) was prepared in which an undoped n-type III-nitride semiconductor layer, an n-type III-nitride semiconductor layer doped with Si (thickness 4 μm), a photoactive layer (thickness 0.15 μm) and a p-type III-nitride semiconductor layer (thickness 0.05 μm) were sequentially stacked on a substrate. On the prepared LED wafer, SiO₂ (thickness 0.9 μm) was sequentially deposited as a first mask layer and Al (thickness 200 nm) was sequentially deposited as a second mask layer, and then, an SOG resin layer with a circular pattern having a diameter of 0.55 nm was transferred onto the second mask layer using a nanoimprint device. Afterwards, the SOG resin layer was cured using RIE, and the residual resin portion of the resin layer was etched through RIE to form a resin pattern layer. Afterwards, the second mask layer was etched using ICP along the pattern, and the first mask layer was etched using RIE. Afterwards, the first electrode layer, the p-type III-nitride semiconductor layer and the photoactive layer were etched using ICP, and then, the doped n-type III-nitride semiconductor layer was etched to a thickness of 0.8 μm, and an LED wafer having multiple LED structures formed by removing the mask pattern layer through KOH wet etching was manufactured. Afterwards, a temporary protective film of SiO₂ was deposited on the LED wafer on which multiple LED structures were formed (72 nm deposition thickness based on a side of the LED structure), and then, the temporary protective film material formed between multiple LED structures was removed through RIE to expose the upper surface of the doped n-type III-nitride semiconductor layer between the LED structures.

Afterwards, the LED wafer on which the temporary protective film was formed was immersed in an electrolyte of a 0.3 M oxalic acid aqueous solution and connected to the anode terminal of a power supply, and the cathode terminal was connected to a platinum electrode immersed in the electrolyte, and then, a voltage of 15 V was applied for 5 minutes to form multiple pores in the thickness direction from the surface of the doped n-type III-nitride semiconductor layer between the LED structures. After the temporary protective film was removed through ICP, the LED wafer was immersed in a bubble-forming solution which was 100% gamma-butyrolactone, and then, ultrasonic waves were irradiated at 160 W and 40 kHz for 10 minutes to collapse the pores formed in the doped n-type III-nitride semiconductor layer using the bubbles generated, thereby manufacturing a plurality of ultra-thin LED elements (diameter 720 nm, thickness 800 nm).

Afterwards, a first electrode line was manufactured by alternately forming multiple first electrodes extending in a first direction at intervals of 2 μm in a second direction perpendicular to the first direction on a quartz material base substrate having a thickness of 500 μm. In this case, the width of the first electrode was 10 μm, the thickness was 0.2 μm, the material of the first electrode was gold, and the area of a region where the ultra-thin LED element was mounted in the first electrode line was set to 1 mm². In addition, an insulating partition wall made of SiO₂ with a height of 0.5 μm was formed on the base substrate to surround the above-mentioned mounting region.

Afterwards, a solution was prepared by mixing 200 prepared ultra-thin LED elements in acetone with a dielectric constant of 20.7, and then, 9 μL of the prepared solution was dropped twice within the above-mentioned mounting region and then, a sine wave AC power of 1 Hz and 10 Vpp was applied to the adjacent first electrode to self-align the ultra-thin LED elements.

Afterwards, a passivation material, which was SiO₂, was deposited using a PECVD method in the region where the ultra-thin LED elements were mounted to a height corresponding to the thickness of the ultra-thin LED elements, and then, multiple second electrodes (width 10 μm, thickness 0.2 μm, interval between electrodes 2 μm, material gold) extending in a second direction perpendicular to the first direction and spaced apart from each other in the first direction were formed on the upper surface of the mounted ultra-thin LED elements to implement an ultra-thin LED electrode assembly.

### Examples 2 to 12

The ultra-thin LED electrode assemblies were manufactured in the same manner as in Example 1, except that the frequency and/or voltage of the power applied to the first electrode were changed as shown in Table 1 below to implement ultra-thin LED electrode assemblies.

### Comparative Examples 1 to 4

The ultra-thin LED electrode assemblies were manufactured in the same manner as in Example 1, except that the frequency of the power applied to the first electrode was changed as shown in Table 1 below to implement ultra-thin LED electrode assemblies.

### Experimental Example 1

The ratio of the ultra-thin LED elements settled on the upper surface of the first electrode relative to the total number of ultra-thin LED elements used in the ultra-thin LED electrode assemblies according to Examples 1 to 12 and Comparative Examples 1 to 4 was evaluated as follows, and the results are shown in Table 1 below.

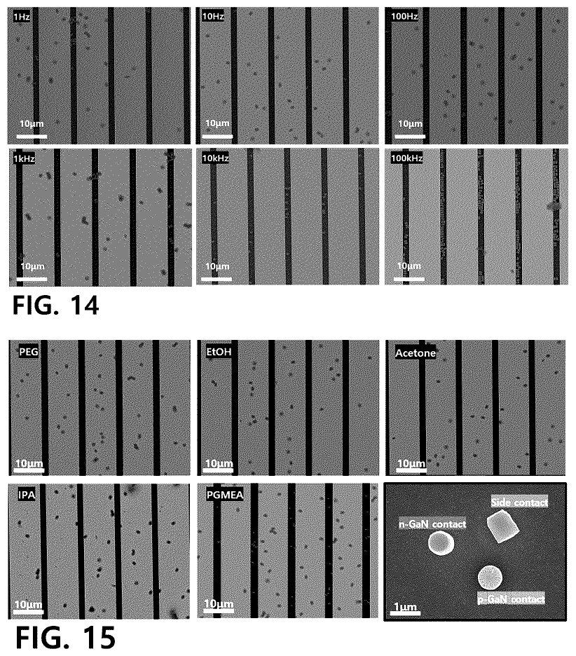

Specifically, during the manufacturing process of the ultra-thin LED electrode assembly, after power was applied and the ultra-thin LED elements were self-aligned, an SEM photograph was taken, and the number of ultra-thin LED elements settled within the upper surface of the first electrode within the unit area (1 mm²) of the first electrode line was counted and shown as a percentage relative to the number of ultra-thin LED elements used in Table 1 below. In addition, SEM images of some regions measured in relation to Examples 1 to 4 and Comparative Examples 2 to 3 are shown in FIG. 14.

In addition, for Examples 1, 9 and 10, damage to the first electrode line was observed using an optical microscope.

As a result of the observation, no damage to the first electrode line was observed for Examples 1 and 9, but for Example 10, the color changed in a part of the first electrode line, and it was confirmed that electrode damage may have occurred. Through this, it can be expected that problems such as electrode short-circuiting may occur if the applied voltage is stronger.

TABLE 1

| | Applied Power | | Settling Ratio Within |
|---|---|---|---|
| | Frequency | Voltage | Upper Surface of First |
| | (Hz) | (Vpp) | Electrode (%) |
| Example 1 | 1 | 10 | 66.0 |
| Example 2 | 5 | 10 | 85.1 |
| Example 3 | 10 | 10 | 89 |
| Example 4 | 100 | 10 | 41.2 |
| Example 5 | 500 | 50 | 40.3 |
| Example 6 | 10 | 1 | 65.2 |
| Example 7 | 10 | 5 | 76.8 |
| Example 8 | 10 | 20 | 93.0 |
| Example 9 | 10 | 40 | 95.1 |
| Example 10 | 10 | 100 | 98.2 |
| Example 11 | 30 | 5 | 67.6 |
| Example 12 | 50 | 5 | 52.3 |
| Comparative Example 1 | 1000 | 10 | 22.3 |
| Comparative Example 2 | 2000 | 50 | 18.5 |
| Comparative Example 3 | 1 × 10⁴ | 50 | 15.3 |
| Comparative Example 4 | 1 × 10⁵ | 50 | 12.1 |

As can be confirmed from Table 1 and FIG. 14, it can be seen that in Examples 1 to 12 where the frequency of the applied power was 500 Hz or less, the settling ratio of the ultra-thin LED element within the upper surface of the first electrode was at least twice as high as in Comparative Examples 1 to 4.

### Examples 13 to 18

The ultra-thin LED electrode assemblies were manufactured in the same manner as in Example 3, except that the type of solvent used to disperse the ultra-thin LED element was changed from acetone to Table 2 below.

### Experimental Example 2

The ultra-thin LED electrode assemblies according to Examples 3 and 13 to 18 were evaluated in the same manner as in Experimental Example 1, and the ultra-thin LED settling ratio within the upper surface of the first electrode, and whether the surface of the ultra-thin LED element contacting the upper surface of the first electrode was the upper layer on the p-type conductive semiconductor layer side, the lower layer on the n-type conductive semiconductor layer side, or the side surface were observed and counted through SEM images. Specifically, among the total ultra-thin LED elements settled within the upper surface, the number of LED elements belonging to a first group in which the lower layer on the n-type conductive semiconductor layer side contacted the upper surface, and the number of LED elements belonging to a second group in which the upper layer on the p-type conductive semiconductor layer side contacted the upper surface were counted, and the drivable mounting ratio among the total ultra-thin LED elements settled within the upper surface was calculated and shown in Table 2 below. Additionally, the SEM photographs of parts of the mounting region of the ultra-thin LED electrode assemblies according to Examples 3 and 13 to 16 are shown in FIG. 15.

TABLE 2

| | | Settling Ratio | |
|---|---|---|---|
| | | Within Upper | Drivable |
| | Solvent (Type/ | Surface of First | Mounting |
| | Dielectric Constant) | Electrode (%) | Ratio (%) |
| Example 13 | PEG/35.5 | 99.69 | 60.51 |
| Example 14 | Ethanol/24.3 | 99.54 | 43.94 |
| Example 3 | Acetone/20.7 | 89 | 19.4 |
| Example 15 | Isopropyl alcohol/18.0 | 87.7 | 15.7 |
| Example 16 | Propylene glycol methyl | 63.87 | 12.44 |
| | ether acetate (PGMEA)/8.3 | | |
| Example 17 | Hexane/2.02 | 5.21 | 0.8 |
| Example 18 | Water (H₂O)/79.9 | 24.21 | 2 |

As can be confirmed from Table 2, in the case of Example 17 where the dielectric constant of the solvent was less than 5 and Example 18 where the dielectric constant exceeded 50, the number of ultra-thin LED elements mounted on the first electrode was significantly reduced.

### Examples 19 to 31

The manufacturing process of ultra-thin LED elements was changed to form a rotation-inducing film on a side surface of the ultra-thin LED element as shown in Table 3 below, or an ultra-thin LED element with an adjusted thickness was used to manufacture ultra-thin LED electrode assemblies.

In this case, the rotation-inducing film was formed on a side surface of the ultra-thin LED element by further performing a process of forming multiple pores on the LED wafer on which multiple LED structures were formed, and then, the temporary protective film was removed through ICP, and before the LED wafer was immersed in a bubble-forming solution which was 100% gamma-butyrolactone, the rotation-inducing film material was deposited to a thickness of 60 nm based on the side surface of the LED structure, and then, the rotation-inducing film material formed between the LED structures was removed through RIE to expose the upper surface of the doped n-type III-nitride semiconductor layer between the LED structures.

In addition, the thickness change of the ultra-thin LED element was controlled by changing the depth of etching the LED wafer.

### Experimental Example 3

The ultra-thin LED electrode assemblies according to Examples 3 and 19 to 31 were evaluated in the same manner as in Experimental Example 1, and the ultra-thin LED settlement ratio and the drivable mounting ratio within the upper surface of the first electrode were calculated and shown in Table 3 below.

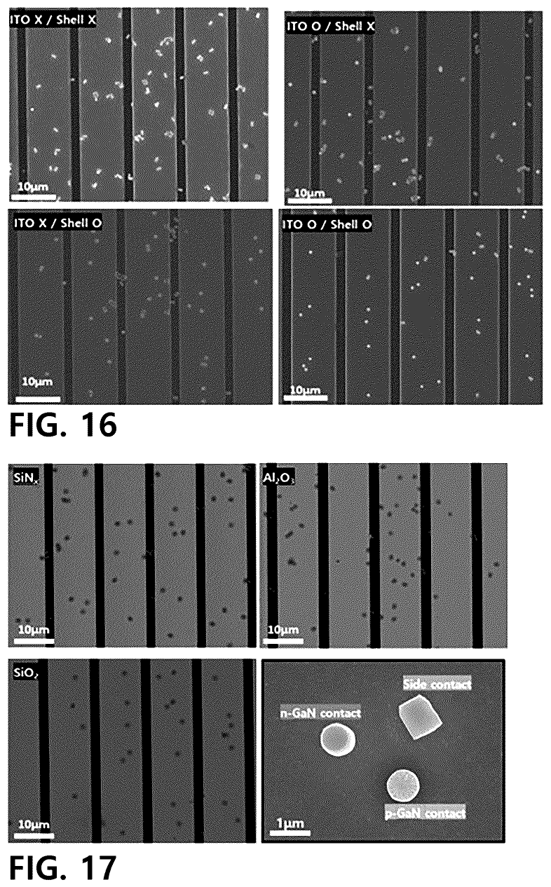

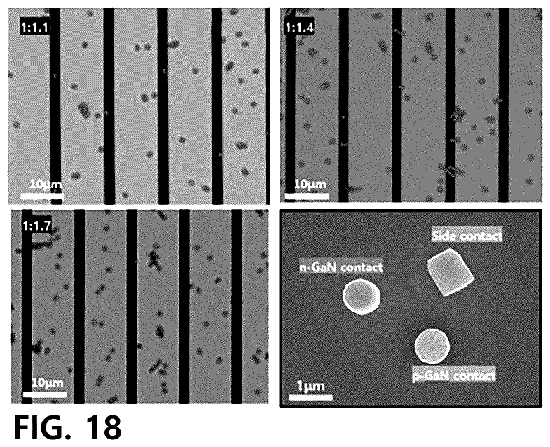

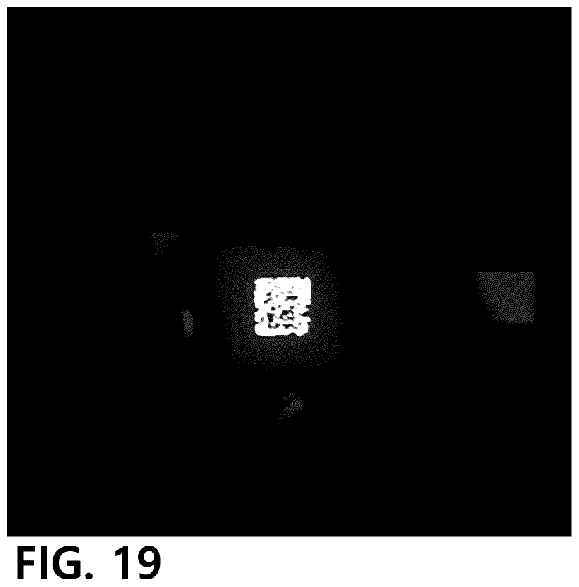

In addition, the SEM images of parts of the mounting region of the ultra-thin LED electrode assemblies according to Examples 3 and 19 to 21 are shown in FIG. 16, the SEM images of parts of the mounting region of the ultra-thin LED electrode assemblies according to Examples 22 to 24 are shown in FIG. 17, and the SEM images of parts of the mounting region of the ultra-thin LED electrode assemblies according to Examples 21 and 25 to 26 are shown in FIG. 18.

TABLE 3

| | | | | Settling | | | | | |
|---|---|---|---|---|---|---|---|---|---|
| | Ultra-thin LED Element | | | Ratio | Contact Area Ratio of Ultra-thin LED | | | | |
| | | Rotation- | | Within | Elements Mounted Within Upper | | | | |
| | Uppermost | inducing | Ratio of | Upper | Surface of First Electrode (%) | | | | |
| | Layer on | Film | Thickness | Surface | | | P-type | | Drivable |
| | P-type | (/Material | (b)/ | of First | N-type | | Semicon- | | Mounting |
| | Semicon- | Dielectric | Diameter | Electrode | Semicon- | Side | ductor | | Ratio |
| | ductor | Constant) | (a) | (%) | ductor | Surface | Side | Total | (%) |
| Example 3 | None | None | 1.11 | 93.87 | 12.9 | 76.9 | 10.2 | 100 | 23.1 |
| Example 19 | ITO | None | 1.11 | 80.32 | 6.8 | 76.4 | 16.8 | 100 | 23.6 |
| Example 20 | None | SiO₂/3.9 | 1.11 | 85.2 | 4.0 | 28.2 | 67.8 | 100 | 71.8 |
| Example 21 | ITO | SiO₂/3.9 | 1.11 | 99.69 | 4.3 | 28.8 | 66.9 | 100 | 71.2 |
| Example 22 | ITO | SiO₂/3.9 | 1.4 | 89.71 | 5.7 | 27.8 | 66.5 | 100 | 72.2 |
| Example 23 | ITO | SiNₓ/6.2 | 1.4 | 89.15 | 8.0 | 49.3 | 42.7 | 100 | 50.7 |
| Example 24 | ITO | Al₂O₃/9.0 | 1.4 | 87.5 | 14.2 | 64.0 | 21.8 | 100 | 36.0 |
| Example 25 | ITO | SiO₂/3.9 | 1.74 | 92.1 | 14.2 | 28.0 | 57.8 | 100 | 72.0 |
| Example 26 | ITO | SiO₂/3.9 | 1.95 | 80.12 | 36.9 | 44.6 | 18.5 | 100 | 55.4 |
| Example 27 | ITO | SiO₂/3.9 | 2.5 | 75.12 | 2.9 | 92.3 | 4.8 | 100 | 7.7 |
| Example 28 | None | ZrO₂/25.0 | 1.1 | 83.1 | 28.2 | 57.5 | 14.3 | 100 | 42.5 |
| Example 29 | None | HfO₂/30 | 1.1 | 81.1 | 25.8 | 59.8 | 14.4 | 100 | 40.2 |
| Example 30 | None | TiO₂/80 | 1.1 | 76.5 | 4.1 | 87.9 | 8.0 | 100 | 12.1 |

As can be confirmed from Table 3, the examples had an ultra-thin LED element settling ratio of 76.5% or more within the upper surface of the first electrode, and it can be seen that the efficiency in moving and settling the ultra-thin LED elements dispersed in the solvent to the upper surface of the first electrode was excellent.

In addition, it can be seen that the examples with the rotation-inducing film had a higher drivable mounting ratio compared to Examples 3 and 19 without the rotation-inducing film. However, in the case of Example 27 where the ratio of thickness (b)/diameter (a) of the ultra-thin LED element exceeded 2.0, and Example 30 where the dielectric constant of the rotation-inducing film was excessive, the drivable mounting ratio was greatly reduced compared to the other examples.

Although one embodiment of the present disclosure has been described above, the spirit of the present disclosure is not limited to the embodiment presented in the present specification, and those skilled in the art who understand the spirit of the present disclosure will be able to easily suggest other embodiments by modifying, changing, deleting or adding components within the scope of the same spirit, but this will also be considered to fall within the spirit of the present disclosure.

1. A method for manufacturing an ultra-thin LED electrode assembly, the method comprising:
injecting a solution having a plurality of ultra-thin LED elements on a first electrode line, wherein at least two first electrodes whose side surfaces are spaced apart are spaced apart from each other;
applying power having a frequency of 500 Hz or less to the first electrode line to form an electric field;
moving ultra-thin LED elements located within the electric field into upper surfaces of the first electrodes; and
forming a second electrode line on the ultra-thin LED elements arranged within the upper surfaces of the first electrodes.

2. The method of claim 1, wherein the power has a frequency of 1 to 500 Hz and a voltage of 5 to 100 Vpp.

3. The method of claim 1, wherein the viscosity of a solvent in the solution is 50 cP or less.

4. The method of claim 1, wherein the dielectric constant (ε) of a solvent in the solution is 5 to 50.

5. The method of claim 1, wherein the ultra-thin LED element is formed by stacking layers comprising a first conductive semiconductor layer, a photoactive layer and a second conductive semiconductor layer, and further comprises a rotation-inducing film surrounding a side surface of the ultra-thin LED element in order to generate a rotational torque based on an axial direction perpendicular to a direction in which the layers are stacked.

6. The method of claim 5, wherein the rotation-inducing film has a dielectric constant (ε) of 3 to 26.

7. The method of claim 1, wherein the ultra-thin LED element has a ratio (b/a) of a thickness (b), which is a length in the stacking direction, to a longitudinal length (a) in a cross-section perpendicular to the stacking direction of the layers, of more than 0 and 2.0 or less.

8. The method of claim 7, wherein the ratio (b/a) for the ultra-thin LED element is more than 0 and 1.8 or less.

9. An ultra-thin LED electrode assembly, comprising:
a first electrode line comprising at least two first electrodes that are spaced apart from each other such that side surfaces thereof are opposite to each other;
a plurality of ultra-thin LED elements comprising a first ultra-thin LED element that is positioned within an upper surface of the first electrode; and
a second electrode line arranged on the first ultra-thin LED element,
wherein a first electrode upper surface settling ratio calculated according to Mathematical Formula 1 below satisfies 40% or more:
$$[ Mathematical Formula 1 ]$$
$$First electrode upper surface settling ratio ( \% ) = \frac{Number of first ultra - thin LED elements}{Total number of ultra - thin LED elements} \times 100$$
wherein the number of ultra-thin LED elements refers to a total number of ultra-thin LED elements placed within a unit area (1 mm²) of the first electrode line and a number of first ultra-thin LED elements.

10. The ultra-thin LED electrode assembly of claim 9, wherein the ultra-thin LED element is formed by stacking a plurality of layers comprising a first conductive semiconductor layer, a photoactive layer and a second conductive semiconductor layer, and comprises a first surface and a second surface facing each other in a thickness direction, and
wherein a drivable mounting ratio, which is a ratio of the total number of a number of third ultra-thin LED elements mounted such that the first surface contacts an upper surface of the first electrode and the second surface contacts a second electrode line and a number of fourth ultra-thin LED elements mounted such that the second surface contacts an upper surface of the first electrode and the first surface contacts a second electrode line among the number of first ultra-thin LED elements arranged within a unit area (1 mm²) of the first electrode line, is 40% or more.

11. The ultra-thin LED electrode assembly of claim 9, wherein an interval between adjacent first electrodes is 2 to 10 μm.

12. The ultra-thin LED electrode assembly of claim 9, wherein the ultra-thin LED element has a thickness of 0.5 to 1.5 μm, which is a length in a direction in which the layers are stacked, and a longitudinal length in a cross-section perpendicular to a direction in which the layers are stacked of 0.5 to 3.0 μm.

13. The ultra-thin LED electrode assembly of claim 10, wherein the first electrode upper surface settling ratio calculated according to Mathematical Formula 1 is 80% or more, and the drivable mounting ratio is 50% or more.

14. A light source, comprising:
the ultra-thin LED electrode assembly according to claim 9.

15. A light source, comprising:
the ultra-thin LED electrode assembly according to claim 10.

16. A light source, comprising:
the ultra-thin LED electrode assembly according to claim 11.

17. A light source, comprising:
the ultra-thin LED electrode assembly according to claim 12.

18. A light source, comprising:
the ultra-thin LED electrode assembly according to claim 13.
